(19) United States
(12) Patent Application Publication
(10) Pub. No.: US 2008/0128592 A1
(43) Pub. Date: Jun. 5, 2008

(54) Light Receiving Element

(76) Inventors: Kazuaki Sawada, Aichi (JP); Yuki Maruyama, Aichi (JP)

Correspondence Address: Matthew K. Ryan;Frommer Lawrence & Haug, 745 Fifth Avenue, New York, NY, 10151, US

(21) Appl. No.: 11/793,560

(22) PCT Filed: Dec. 20, 2005
(86) PCT No.: PCT/JP05/23309

§ 371 Date: Jun. 19, 2007

(30) Foreign Application Priority Data
Dec. 21, 2004 (JP) 2004-369895

(51) Int. Cl. H03G 3/20; H01L 27/146

(52) U.S. Cl. 250/214 AG; 257/292; 257/E27.133

(57) ABSTRACT

In a photosensor for composing pixels of an image sensor, a wide dynamic range having self-suppression action in the sensor unit in every pixel is realized. The photosensor includes a semiconductor substrate, a first electrode film formed on the semiconductor substrate, an insulator film being between the semiconductor substrate and the first electrode film, passing an incident light and receiving a gate voltage, and a first diffusion layer adjacent to the first electrode film, in which the first electrode film and the first diffusion layer are connected by wiring.

### TECHNICAL FIELD

The present invention relates to a photosensor, more particularly to expansion of dynamic range of a photogate-type photosensor.

### BACKGROUND ART

Wide dynamic range sensors have been recently proposed on the basis of various non-linear reading methods as follows.

A method of using a non-linear portion of an MOS (Metal Oxide Semiconductor) characteristic.

A method of using a plurality of sensors that vary in degrees of sensitivity, and of making their outputs combine into a single pixel.

A method of varying the time required for accumulation.

### DISCLOSURE OF THE INVENTION

### Problems that the Invention is Intended to Solve

However, in the method according to which a non-linear portion of an MOS characteristic is used, a buried photodiode structure is not formed, a level of dark current cannot be reduced, and an after-image is left over in a region of low illumination.

In the method according to which a plurality of sensors that vary in degrees of sensitivity is used and in combinations in the formation of a single pixel, the area of the single pixel becomes too wide.

In the method according to which the time required for accumulation is varied, the reading circuit is complicated, and the size of the circuit becomes too large.

It is hence an object of the invention to provide an image sensor of a wide dynamic that incorporate having a self-suppression function of the sensor in each pixel, by means of wiring appropriately in each pixel, and by means of setting a threshold voltage of the sensor at an appropriate value.

### Means for Solving the Problems

A first aspect of the invention has the following structure in order to achieve the above object. In other words, the invention relates to a photosensor including:

a semiconductor substrate,

a first electrode film formed on the semiconductor substrate, an insulator film being between the semiconductor substrate and the first electrode film, the first electrode film passing incident light and being subjected to a gate voltage, and

a first diffusion layer that is formed adjacent to the first electrode film,

wherein the first electrode film and the first diffusion layer are connected by wiring.

In the photosenssor thus composed, the electric charge that is generated within a charge acquisition region positioned beneath the first electrode film and that is acquired by the light that passes through the first electrode film falls into the well positioned beneath the first diffusion layer adjacent the first electrode film and is thus accumulated therein. As a result, the potential of the first diffusion layer is modified. When this modification in potential is fed back to the first electrode film through the wiring, the potential in the charge acquisition region that is positioned beneath the first electrode film is modified, and the level of efficiency in charge acquisition within the charge acquisition region is lowered. In consequence, the electric charge can be accumulated in the well under the first diffusion layer over a long periods of time. As a result, the dynamic range of the photosensor is automatically expanded.

According to a second aspect of the invention, with regard to the photosensor of the first aspect, the semiconductor substrate is doped as a first conductive type, the first diffusion layer is doped as a second conductive type that is different from that of the semiconductor substrate, and the portion of the semiconductor substrate that is positioned beneath the first electrode film is doped as a first conductive type at a higher level of concentration than in the other semiconductor substrate.

By means of doping the region beneath the first electrode film, i.e. the charge acquisition region at a higher level, it is possible to make the level of efficiency in charge acquisition within the charge acquisition region modify in accordance with the change in the potential of the first diffusion layer.

According to a third aspect of the invention, with regard to the second aspect of the invention, the semiconductor substrate is a silicon substrate, and the first conductive type and the second conductive type are respectively p-type and n-type.

By virtue of such a configuration, electrons can be utilized as an electric charge.

According to a fourth aspect of the invention, the first electrode film is a polycrystal silicon doped with impurities. Hence, a photosensor can be manufactured by means of a generally known semiconductor manufacturing process.

According to a fifth aspect of the invention, with regard to the first to fourth aspects of the invention, a second diffusion layer is further provided, and a transfer gate is formed between the second diffusion layer and the first diffusion layer.

By virtue of such a configuration, by means of operating the voltage of the transfer gate, the electric charge that has accumulated in the accumulation well provided for purposes of accumulation of charge can be transferred (moved) to an accumulation well provided for purposes of conversion of voltage. As a result, correlation double sampling (CDS) can be applied with ease, and hence elimination of noise becomes possible

Thus, an image sensor is composed by arraying the photosensors defined in the first to fifth aspects of the invention as a pixcl, either in a single dimension or multi-dimensionally.

In the invention, a charge means wither an electron or a hole. When an electron is acquired, the p-type silicon semiconductor substrate is used as in the third aspect of the invention. As a result of the use of a diffusion layer doped with n-type impurities, the charge acquisition region becomes the high potential side barrier, and the diffusion layer becomes the accumulation well. In that configuration, the potential of the diffusion layer falls down when the electrons are accumulated in the diffusion layer. As a result, the potential of the first electrode film that is wired to the diffusion layer is lowered, and the energy level of the charge acquisition region is raised. Accordingly, within the charge acquisition region, the level of efficiency in acquiring the charge is lowered, and electrons can be accumulated in the accumulation well of the diffusion layer over long periods of time.

When an electron is handled as the charge, a silicon substrate or the like may be used.

When a hole is acquired as the charge, an n-type silicon (Si) substrate may be used. As a result of the use of a diffusion layer doped with p-type impurities, the charge acquisition region becomes the low potential side barrier, and the diffusion layer becomes the accumulation well. In such a configuration, when holes are accumulated in the diffusion layer, the potential of the diffusion layer is raised. As a result, the potential of the first electrode film wired to the diffusion layer is raised, and hence the energy level of the charge acquisition region is lowered. Accordingly, within the charge acquisition region, the level of efficiency in acquiring charge is lowered, and holes can be accumulated in the accumulation well of the diffusion layer over long periods of time.

When a hole is handled as the charge, as well as the Si substrate, a film made of an amorphous silicon, or of a polycrystal silicon may also be used.

### BRIEF DESCRIPTION OF THE DRAWINGS

FIG. 1 is a sectional view and a peripheral circuit diagram illustrating a configuration of a photogate-type photosensor in an embodiment of the invention.

FIG. 2 is a diagram of potential distribution of the photogate-type photosensor in the embodiment.

FIG. 3 is a diagram of potential distribution of the photogate-type photosensor in an example of prior art.

FIG. 4 is a timing chart illustrating differences in operation between the prior art and the embodiment.

FIG. 5 is a timing chart of operations according to the prior art.

FIG. 6 is a timing chart of a wide dynamic range operation in the embodiment.

FIG. 7 is a block diagram of a CMOS image sensor of a wide dynamic range incorporating a self-suppression function in each pixel.

FIG. 8 is a block diagram of a photogate-type photosensor in another embodiment.

FIG. 9 is a diagram of potential distribution of a photogate-type photosensor in another embodiment.

### BEST MODE FOR CARRYING OUT THE INVENTION

### Embodiment 1

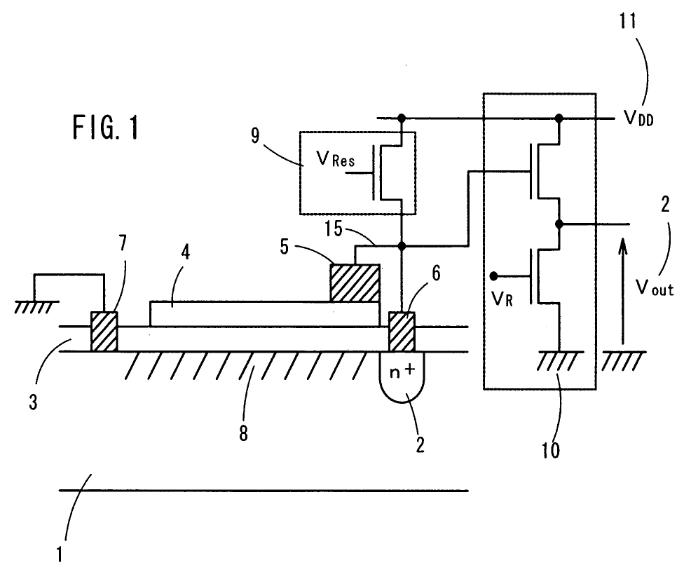

FIG. 1 is a sectional view and a peripheral circuit diagram illustrating a photosensor in an embodiment of the invention. Reference numeral 1 is a p-type semiconductor substrate; 2 is an n-plus diffusion layer formed on the p-type silicon substrate; 3 is a silicon oxide (SiO2) film formed on the p-type silicon substrate 1; 6 is an aluminum (Al) electrode connected to the n-plus diffusion layer 2; 4 is a polycrystal silicon (poly-Si) film doped with impurities and formed on the silicon oxide film 3; and 5 is a gate electrode connected to the polycrystal silicon film 4. The polycrystal silicon film 4 functions as a first electrode film that allows light to permeates through the silicon oxide film 3 as well as itself 4. Reference numeral 7 is an electrode connected and grounded to the substrate. Reference numeral 8 is a charge acquisition region that is designed to vary, by means of voltage change of the n-plus diffusion layer 2, the capacity for acquisition of electrons beneath the polycrystal silicon film, and that has impurities diffused (p-type diffusion region) at a higher level of concentration than in other portions of the p-type silicon substrate. Reference numeral 9 is a switch for applying voltage to the gate electrode 5, and to the n-plus diffusion layer 2. Reference numeral 10 is a source-follower circuit for converting the electric charge accumulated in the n-plus diffusion layer 2 into voltage. Reference numeral 11 is a supply voltage for driving the switch 9 and the source-follower circuit 10; and 12 is an output voltage converted into voltage by the source-follower circuit.

Reference numeral 15 is a bypass for wiring between the diffusion layer 2 and the first electrode film 4.

Such a structure can be manufactured by means of a well-known semiconductor manufacturing technology.

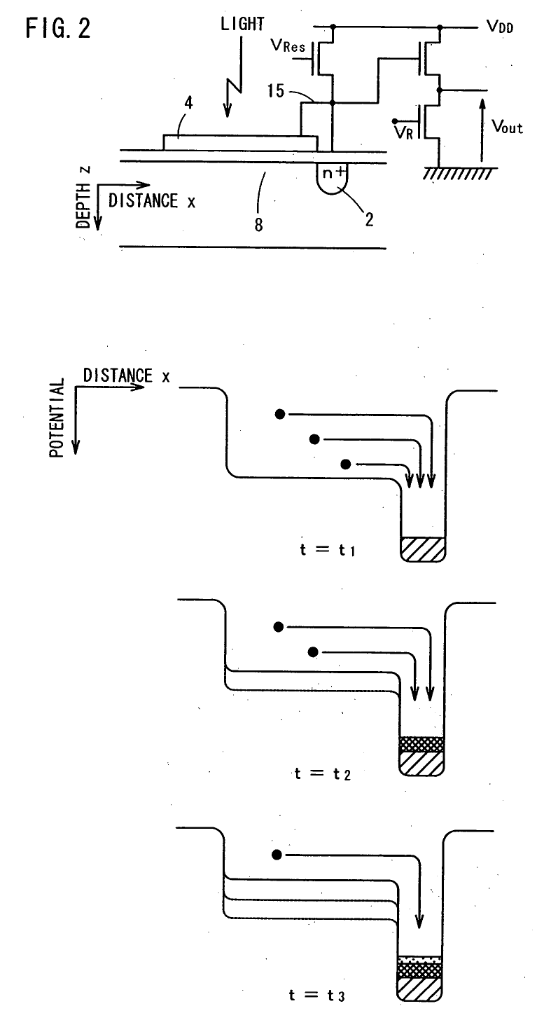

In the device of the embodiment having such a structure, as illustrated in FIG. 2, since the first electrode film 4 and the n-plus diffusion layer 2 are connected, the potential of the first electrode film 4 is identical to the potential of the n-plus diffusion layer 2. Since at t=t1, the gate voltage is sufficiently large, an electric charge corresponding to the incident light is acquired in the charge acquisition region 8, and is accumulated in the accumulation well formed in the diffusion layer 2. As a result, the potential of the diffusion layer 2 is lowered, and this drop in potential leads to a reduction in the voltage of the gate electrode 5. When the potential of the gate electrode 5 is lowered, the potential of the first electrode film 4 drops, and when the electric field applied to the charge acquisition region becomes weaker, the potential of the charge acquisition region drops. Hence, efficiency in acquiring charge is lowered, and at t=t2, the amount of charge acquired is less than at t=t1. Hence at t=t3, too, there still remains scope for accumulating the charge in the charge well within the n-plus diffusion layer.

By means of this operation, the dynamic range can be expanded.

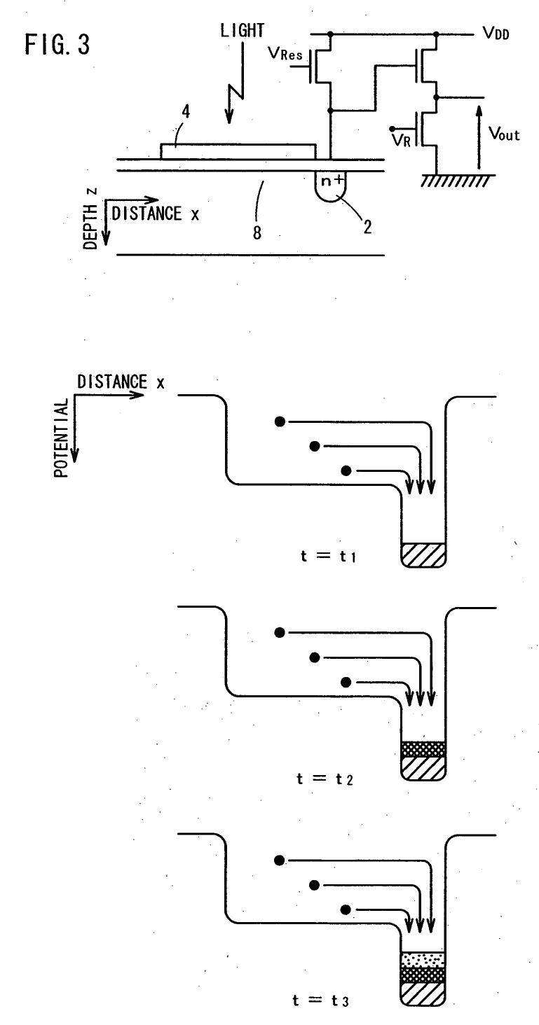

FIG. 3 is a sectional view of a normal photogate-type photosensor and its potential distribution. In this device, a specific voltage Vg is applied to the first electrode film. On the assumption that the intensity of incident light is constant, an amount of charge is accumulated that is proportionate to the time during which the charge has been accumulated in the accumulation well formed within the n-plus diffusion layer. In FIG. 3, the accumulation well has been completely filled with electric charge at t=t3. As a result, unless electric charge is discharged from the accumulation well, any charge that is subsequently acquired in the charge acquisition region is not reflected as a signal. In other words, the dynamic range of a photosensor is limited by the depth of the accumulation well within the diffusion layer 2.

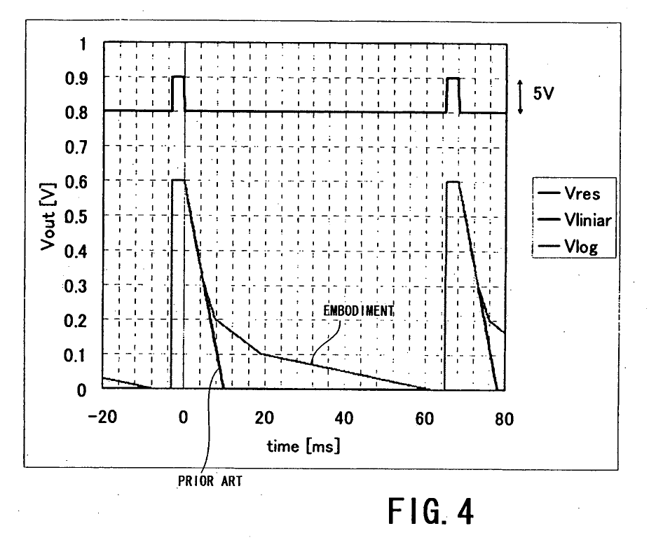

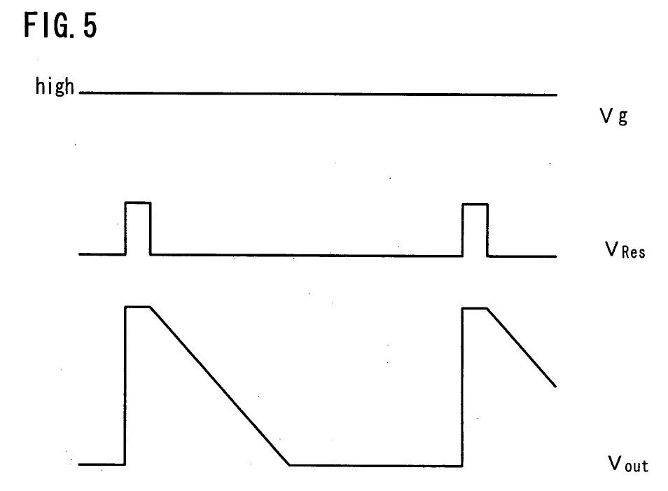

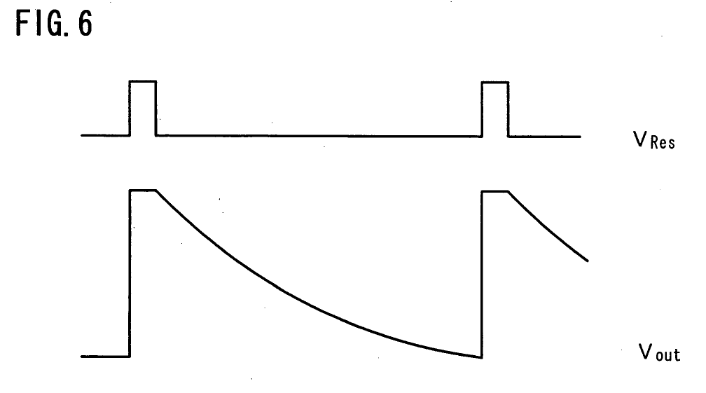

As, for example, the photosensor in FIG. 1, the concentration of impurities in each region is 1.5×10¹⁶ cm⁻³ in a p-type semiconductor substrate 1, 1.5×10¹⁹ cm-³ in an n-plus diffusion layer 2, and 1.5×10¹⁷ cm⁻³ in a p-type diffusion region 8, Vdd10 and Vres9 are 5 V, respectively, and the gain of the source-follower circuit is 0.7. FIG. 4 illustrates the waveform of a conventional photogate-type after voltage conversion, and the waveform of the invention (measured by assuming that feedback to the photogate has been undertaken with the use of the conventional type). FIG. 5 is a timing chart of the conventional type, and FIG. 6 is a timing chart of the invention. As illustrated in the diagrams, the dynamic range can be expanded.

By means of using the photosensor of the embodiment as the pixel and, by means of arraying either in a single dimension or multi-dimensionally, an image sensor can be obtained in which each pixel has a self-suppression function.

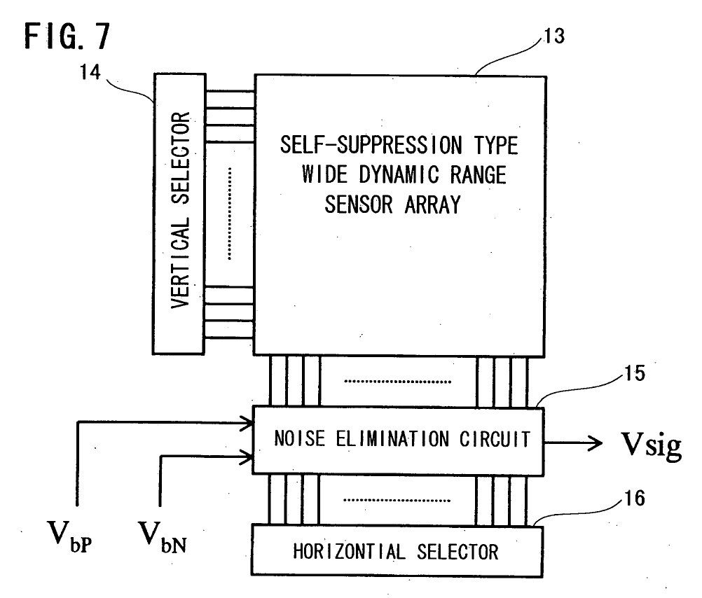

FIG. 7 is a block diagram of a CMOS image sensor that is of a wide dynamic range, and that has a self-suppression function in each pixel. In this diagram, reference numeral 13 is a sensor array; 14 is a vertical selector (V. scanner); 15 is a noise elimination circuit (column CDS); 16 is a horizontal selector (H. scanner); Vsig is a light signal output; and Vbn, Vbp are biases for driving of low current.

As explained above, the invention produces the following effects:

Makes provision for the expansion of the dynamic range of the photogate-type photosensor; and

by use of the photosensor of the embodiment, provides a CMOS transistor that is of a wide dynamic range, and that incorporates a self-suppression function in each pixel.

### Embodiment 2

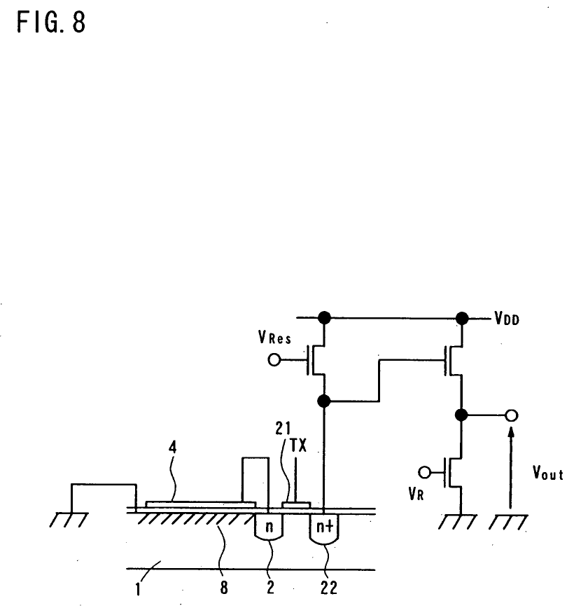

FIG. 8 illustrates a configuration of a photogate-type photosensor in another embodiment of the invention. The same elements as in FIG. 1 are identified with identical reference numerals, and an explanation is therefore omitted.

Reference numeral 21 is a transfer gate electrode that is capable of electrically isolating the P-type substrate 1 into a light detection region (an accumulation well for accumulation of charge) and a voltage conversion region (an accumulation well for conversion of voltage) . The transfer gate electrode 21 is turned on when a charge is accumulated in the n-type diffusion layer 2, and is capable of transferring the charge to the n-plus diffusion layer 22.

Reference numeral 22 is an n-plus diffusion layer that accumulates charge transferred from the n-type diffusion layer 2, and that reads out its voltage. The voltage that is read out is an output signal of the photosensor.

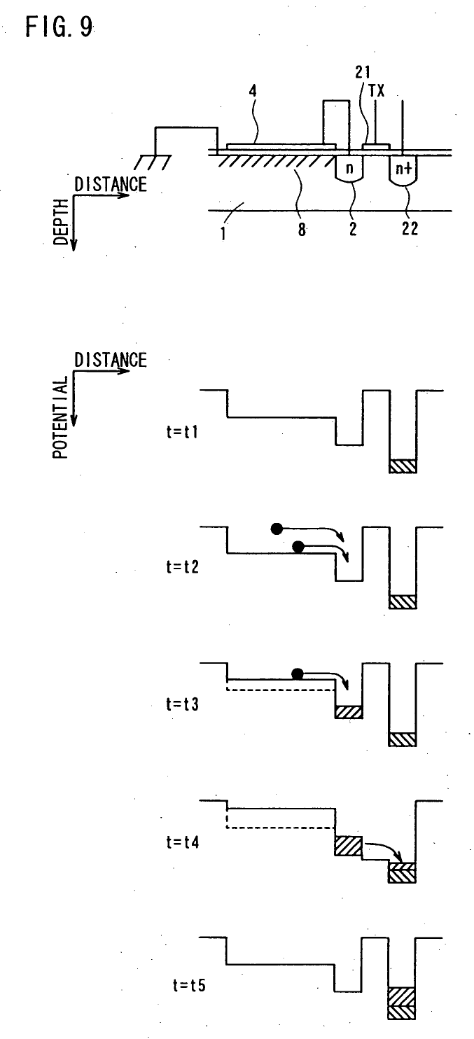

FIG. 9 illustrates the potential distribution of a photogate-type photosensor.

If, after use on a previous occasion, a charge is accumulated in the n-plus diffusion layer 22, this charge is reset (erased) (t=t1), a reset signal is read in, and the accumulation of charge is commenced (t=t2). Immediately after the start, the level of gate voltage is sufficiently high, charge corresponding to the incident light is acquired in the charge acquisition region 8, and this charge is accumulated in the accumulation well that has been formed within the n-type diffusion layer 2. As a result, the potential of the n-type diffusion layer 2 drops, and the voltage of the Al electrode 4 connected to this n-type diffusion layer 2 is also lowered (t=t3). Because of this decline in potential of the Al electrode 4, the electric field applied to the charge acquisition region 8 becomes weak, and the potential of the charge acquisition region 8 is lowered. Hence, the effects of acquiring charge by means of photoelectric effects are lowered, and the amount of charge acquired is smaller at t=t3 than at t=t2. Thus, sensitivity of the sensor can be adjusted automatically. In other words, in circumstances of a low degree of illumination, the extent of change in voltage is small, the potential of the charge acquisition region 8 can be maintained at a high level, and the level of efficiency in terms of photoelectric conversion is high. In circumstances of a high degree of illumination, the extent of change in voltage is substantial, the potential of the charge acquisition region 8 is lowered, and the level of efficiency in terms of photoelectric conversion declines.

After the charge has been accumulated within the n-type diffusion layer 2, in order to read out this charge, the transfer gate 21 is turned on. As a result, the potential barrier that constitutes the accumulation well is removed, and the charge is transferred to the n-plus diffusion layer 22 that exists within the voltage conversion region (t=t4). The voltage of the n-plus diffusion layer 22 is read out as the output.

In contrast, the charge accumulated within the n-type diffusion layer 2 is lost, the voltage is not fed back to the Al electrode 4, and the potential in the charge acquisition region 8 returns to the same level of potential as existed in the initial state (t=t5).

After the voltage in the n-plus diffusion layer 22 has been read out, the charge in the n-plus diffusion layer 22 is reset so as to acquire the subsequent charge.

Thus, since the light detection region (accumulation well for accumulation of charge) and the voltage conversion region (accumulation well for conversion of voltage) are isolated electrically, CDS (correlation double sampling) can be applied with ease, and noise can accordingly be eliminated.

The invention is not limited to the foregoing embodiments and explanations. Other modified examples not departing from the true spirit of the invention, and within the range easily conceived by those skilled in the art are also embraced within the scope of the invention.

1. A photosensor comprising:
a semiconductor substrate,
a first electrode film formed on the semiconductor substrate, an insulator film being between the semiconductor substrate and the first electrode film, the first electrode film passing an incident light and being subjected to a gate voltage, and
a first diffusion layer that is formed adjacent to the first electrode film,
wherein the first electrode film and the first diffusion layer are connected by wiring.

2. A photosensor comprising, wherein the semiconductor substrate is doped as a first conductive type, the first diffusion layer is doped as a second conductive type that is different from that of the semiconductor substrate, and the portion of the semiconductor substrate that is positioned beneath the first electrode film is doped as a first conductive type at a higher level of concentration than in the other semiconductor substrate.

3. A photosensor comprising, wherein the semiconductor substrate is a silicon substrate, and the first conductive type is a p-type and the second conductive type is an n-type.

4. The photosensor of claim 1, wherein the first electrode film is a polycrystal silicon doped with impurities.

5. The photosensor of claim 1, further comprising a second diffusion layer, wherein a transfer gate is formed between the second diffusion layer and the first diffusion layer.

6. An image sensor, wherein a photosensor of claim 1 is used as a pixel.

7. A photosensor comprising a charge acquisition region positioned beneath a light-permeable first electrode film, and a diffusion layer that is contiguous with the charge acquisition region,
wherein the potential of the diffusion layer that has been modified by the charge acquired in the charge acquisition region is fed back to the first electrode film.

8. A control method for a photosensor which is featured by a charge acquisition region being positioned beneath a light-permeable first electrode film, and a diffusion layer being contiguous with the charge acquisition region, the control method characterized by:
adjusting the dynamic range of the photosensor by means of feeding back to the first electrode film the potential of the diffusion layer that has been changed by the charge acquired in the charge acquisition region.
